(19) United States
(12) Patent Application Publication
(10) Pub. No.: US 2001/0041412 A1
(43) Pub. Date: Nov. 15, 2001

(54) Method of manufacturing a semiconductor device

(76) Inventor: Hiroaki Takasu, Chiba-shi (JP)

Correspondence Address: Adams & Wilks, 31st Floor, 50 Broadway, New York, NY, 10004, US

(21) Appl. No.: 09/778,460

(22) Filed: Feb. 7, 2001

(30) Foreign Application Priority Data
May 8, 2000 (JP) 2000-134839

(51) Int. Cl. H01L 21/8238; H01L 21/20

(52) U.S. Cl. 438/381; 438/384; 438/210; 438/200

(57) ABSTRACT

The present invention provides a method of manufacturing a semiconductor device having a bleeder resistance circuit in which the resistance value does not fluctuate in response to the stress applied thereto. A thin film resistor of the semiconductor device manufactured by a manufacturing method according to the present invention is constituted of a P-type thin film resistor formed of a P-type semiconductor thin film and an N-type thin film resistor formed of an N-type semiconductor thin film in order to cancel the changes of the resistance values thereof when the stress is applied thereto. In addition, in the process of forming a source/drain of an NMOS transistor, at the same time, a low resistance region in an N-type polycrystalline silicon resistor is formed, while in the process of forming a source/drain of a PMOS transistor, at the same time, a low resistance region in a P-type polycrystalline silicon resistor is formed.

### BACKGROUND OF THE INVENTION

1. Field of the Invention

The present invention relates in general to a semiconductor device, and more particularly to a semiconductor device having thin film resistors, a bleeder resistance circuit employing thin film resistors, and a semiconductor device having such a bleeder resistance circuit.

2. Description of the Related Art

Conventionally, there have been used a large number of resistors each of which is made of a semiconductor thin film such as a polycrystalline silicon film, and a large number of bleeder resistance circuits each employing such resistors. In this connection, there have been known the resistors each of which is made of a semiconductor thin film of one conductivity type of an N type or a P type.

However, in the conventional thin film resistors, there arises a problem in that in the case where the stress is applied to each of the thin film resistors, such as the case where the thin film resistors are resin-packaged, the resistance values thereof are changed so that in the bleeder resistance circuit, the voltage dividing ratio may often fluctuate after completion of the resin packaging.

### SUMMARY OF THE INVENTION

In the light of the foregoing, the present invention has been made in order to solve the above-mentioned problem associated with the prior art, and it is therefore an object of the present invention to present a manufacturing method for providing a highly accurate bleeder resistance circuit in which the integrated initial resistance value is still held as it is even after having been resin-packaged so that the accurate voltage dividing ratio can be held therein, and a highly accurate semiconductor device employing such a bleeder resistance circuit, e.g., a semiconductor device such as a voltage detector or a voltage regulator.

In order to attain the above-mentioned object, according to the present invention, there is provided a method of manufacturing a semiconductor device in which an NMOS transistor and a PMOS transistor are both formed on a semiconductor substrate, and an N-type thin film resistor formed of an N-type semiconductor thin film on a field oxide film and a P-type thin film resistor formed of a P-type semiconductor thin film thereon are combined with each other to form a semiconductor thin film resistor, the method including: the process of forming simultaneously a source/drain region of the above-mentioned NMOS transistor and a low resistance region of the above-mentioned N-type thin film resistor; and the process of forming simultaneously a source/drain of the above-mentioned PMOS transistor and a low resistance region of the above-mentioned P-type thin film resistor.

In this connection, each of a thin film resistor of a bleeder resistance circuit employing the thin film resistors is constituted by a P-type thin film resistor formed of a P-type semiconductor thin film and an N-type thin film resistor formed of an N-type semiconductor thin film. In addition, the bleeder resistance circuit may be provided such that the resistance value as one unit is defined on the basis of the resistance value which is formed in combination of a P-type thin film resistor and an N-type thin film resistor, whereby the change in the resistance value of the P-type thin film resistor and the change in the resistance value of the N-type thin film resistor due to the piezo electric effect as will be described below are cancelled each other.

The change of the resistance value due to the piezo electric effect and the influence exerted on the bleeder resistance circuit will hereinafter be described.

While when applying the stress to the thin film resistor, the resistance value of the thin film resistor is changed due to the so-called piezo electric effect, the direction of the change of the resistance value of the P-type thin film resistor is opposited to that of the change of the resistance value of the N-type thin film resistor. This phenomenon was also confirmed on the basis of the experimentations made by the present inventors. For example, in such a case, the resistance value of the P-type thin film resistor is decreased, while the resistance value of the N-type thin film resistor is increased (the direction of the change in the resistance value of the thin film resistor depends on the direction of application of the stress thereto).

Since if the IC is resin-packaged, then the stress is generated, as described above, the resistance value of the thin film resistor is changed due to the piezo electric effect. While the bleeder resistance circuit is provided in order to obtain the accurate voltage dividing ratio, since the resistance values of the individual resistors are changed in such a case, the voltage dividing ratio also correspondingly fluctuates.

Since the thin film resistor according to the present invention is constituted of the P-type thin film resistor formed of the P-type semiconductor thin film and the N-type thin film resistor formed of the N-type semiconductor thin film, even in the case where the stress is applied thereto, the change of the resistance value can be prevented. In addition, since in the bleeder resistance circuit, the resistance value as one unit is defined on the basis of the resistance value which is formed in combination of the P-type thin film resistor and the N-type thin film resistor, even if the stress is applied thereto, then the changes in the resistance values of the individual resistors can be cancelled each other to hold the accurate voltage dividing ratio.

The thin film resistor of the semiconductor device according to the present invention is constituted of the P-type thin film resistor which is formed of the P-type semiconductor thin film and the N-type thin film resistor which is formed of the N-type semiconductor thin film. Therefore, even when the stress is applied thereto due to the resin-packaging, the changes in the resistance values of the individual resistors can be cancelled each other to hold the integrated initial resistance value thereof as it is. In addition, in the bleeder resistance circuit, since the resistance value as one unit is defined on the basis of the resistance value which is formed in combination of the P-type thin film resistor and the N-type thin film resistor, the accurate voltage dividing ratio can be held. By employing such a bleeder resistance circuit, the more highly accurate semiconductor devices, e.g., the semiconductor devices such as a voltage detector and a voltage regulator can be obtained.

### BRIEF DESCRIPTION OF THE DRAWINGS

The above and other objects as well as advantages of the present invention will become clear by the following description of the preferred embodiments of the present invention with reference to the accompanying drawings:

FIGS. 1A to 1G are schematic cross sectional views showing the steps of a method of manufacturing a semiconductor device according to the present invention;

FIG. 2 is a circuit diagram, partly in block diagram, showing a configuration of an embodiment of a voltage detector to which a bleeder resistance circuit according to the present invention is applied; and

FIG. 3 is a circuit diagram, partly in block diagram, showing a configuration of an embodiment of a voltage regulator to which a bleeder resistance circuit according to the present invention is applied.

### DETAILED DESCRIPTION OF THE PREFERRED EMBODIMENTS

The preferred embodiments of the present invention will hereinafter be described with reference to the accompanying drawings.

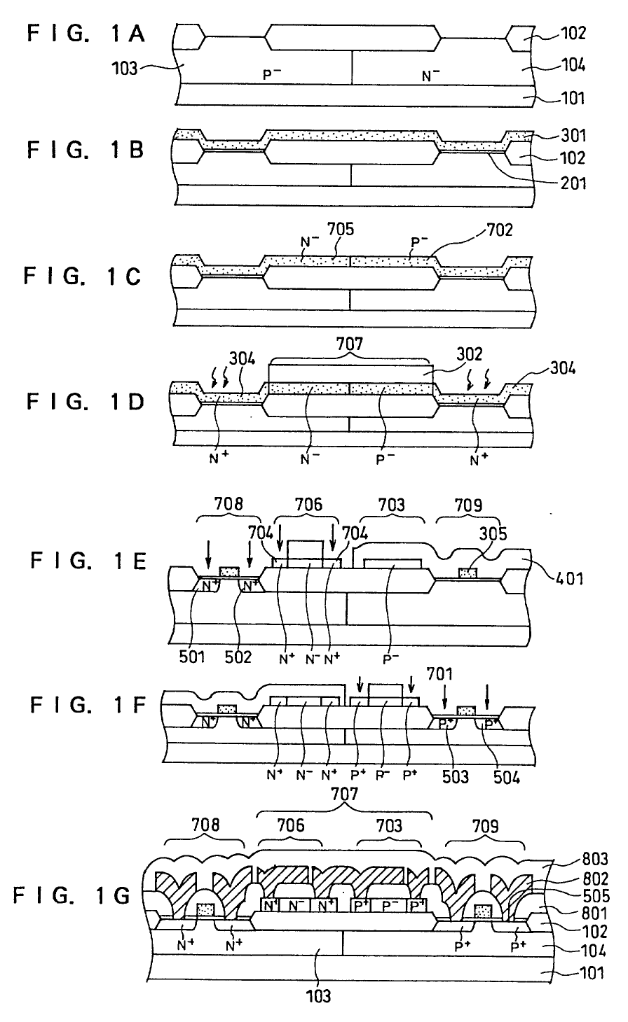

FIGS. 1A to 1G are schematic cross sectional views showing the steps of a method of manufacturing a semiconductor device according to the present invention.

First of all, as shown in FIG. 1A, a P-type well region 103 as a low impurity concentrated P-type region and an N-type well region 104 as a low impurity concentrated N-type region are formed in a semiconductor substrate 101 by utilizing the normally known ion implantation method and through the impurity diffusion process by the suitable heat treatment, and then a field oxide film 102 is selectively formed by utilizing the so-called LOCOS (Local Oxidation of Silicon) method. In this connection, while not particularly illustrated, as may be necessary, a relatively high impurity concentrated region for the channel stop for the element isolation may be formed below the bottom face of the field oxide film 102. In addition, since one of the P-type well region 103 and the N-type well region 104 is not necessarily required, it may not be formed.

Next, as shown in FIG. 1B, a gate oxide film 201 having a predetermined thickness is formed in the region in which a MOS transistor will be formed later. In this connection, before and after the formation of the gate oxide film 201, as may be necessary, the ion implantation for the threshold control of the MOS transistor may be carried out. Thereafter, a polycrystalline silicon film 301 is deposited on the whole surface of the substrate by utilizing the CVD method or the like.

Next, as shown in FIG. 1C, the polycrystalline silicon film 301 is selectively covered with a photo resist film, and then an N-type high resistance region 705 into which a relatively small amount of N-type impurities such as phosphorus (e.g., with a dose of 1E14 atoms/cm²) are implanted by utilizing the ion implantation method and a P-type high resistance region 702 into which a P-type impurities such as boron are implanted by utilizing the ion implantation method are both formed.

Next, as shown in FIG. 1D, the region, which will become a resistor 707 later, on the polycrystalline silicon film 301 located on the field oxide film 102 is covered with a mask oxide film 302 such as a CVD oxide film, and phosphorus is introduced into the unmasked polycrystalline silicon film 301 other than that region by utilizing the solid phase diffusion method or the like to form a high impurity concentrated polycrystalline silicon film 304 which has the sufficient low resistance for intended use of the wiring.

Next, as shown in FIG. 1E, after the mask oxide film 302 has been removed by the solution of hydrofluoric acid or the like and the polycrystalline silicon film 301 is selectively etched away with a gate electrode 305 of the MOS transistor, a P-type polycrystalline silicon resistor 703 and an N-type polycrystalline silicon resistor 706 left, the region other than an N-type MOS transistor region 708, and an N-type low resistance region 704 within an N-type polycrystalline silicon resistor 706 is covered with a photo resist film to implant N-type impurities such as phosphorus thereinto by utilizing the ion implantation method. Through this process, both of an N-type source region 501 and an N-type drain region 502 are formed in the NMOS transistor region 708, and at the same time, an N-type low resistance region 704 is formed in the N-type polycrystalline silicon resistor 706.

Next, as shown in FIG. 1F, the region other than a PMOS transistor region 709, and a P-type low resistance region 701 within the P-type polycrystalline silicon resistor 703 is covered with a photo resist film to implant P-type impurities such as boron thereinto by utilizing the ion implantation method. Through this process, both of a P-type source region 503 and a P-type drain region 504 are formed in the PMOS transistor region 709, and at the same time, a P-type low resistance region 701 is formed in the P-type polycrystalline silicon resistor 703.

Subsequently, in conformity with the normal IC manufacturing process, an intermediate insulating film 801 is formed, a contact hole 505 is formed in a predetermined position, a wiring 802 made of aluminium or the like is formed, and a predetermined pattern is obtained by the etching. Then, a protection film 803 is formed, thereby completing the semiconductor device as shown in FIG. 1G.

Now, with respect to the resistance value of a resistor 707 which is obtained in combination of the P-type polycrystalline silicon resistor 703 and the N-type polycrystalline silicon resistor 706, even when the stress is applied thereto due to the resin-packaging, since the change in the resistance value of the P-type polycrystalline silicon resistor 703 and the change in the resistance value of the N-type polycrystalline silicon resistor 706 can be cancelled each other, the integrated initial resistance value can be held as it is.

In this connection, while in FIG. 1, there has been shown an example of combining one P-type polycrystalline silicon resistor 703 and one N-type polycrystalline silicon resistor 706 with each other, it is to be understood that a plurality of P-type polycrystalline silicon resistors 703 and a plurality of N-type polycrystalline silicon resistors 706 may be combined with each other to form one resistor 707.

In addition, if the resistor 707 which is obtained in combination of the P-type polycrystalline silicon resistor 703 and the N-type polycrystalline silicon resistor 706 shown in FIG. 1G is defined as one unit of the bleeder circuit, and also a plurality of resistors 707 are formed to configure the overall bleeder circuit, even when the stress is applied thereto due to the resin-packaging, the accurate voltage dividing ratio can be held as it is. By employing such a bleeder resistance circuit, the highly accurate semiconductor devices, e.g., the semiconductor devices such as a voltage detector and a voltage regulator can be obtained.

According to a method of manufacturing a semiconductor device of the present invention, in the process of forming the N-type source region 501 and the N-type drain region 502 of the NMOS transistor region 708, at the same time, the N-type low resistance region 704 is formed in the N-type polycrystalline silicon resistor 706, while in the process of forming the P-type source region 503 and the P-type drain region 504 of the PMOS transistor region 709, at the same time, the P-type low resistance region 701 is formed in the P-type polycrystalline silicon resistor 703. Therefore, the manufacturing process can be simplified.

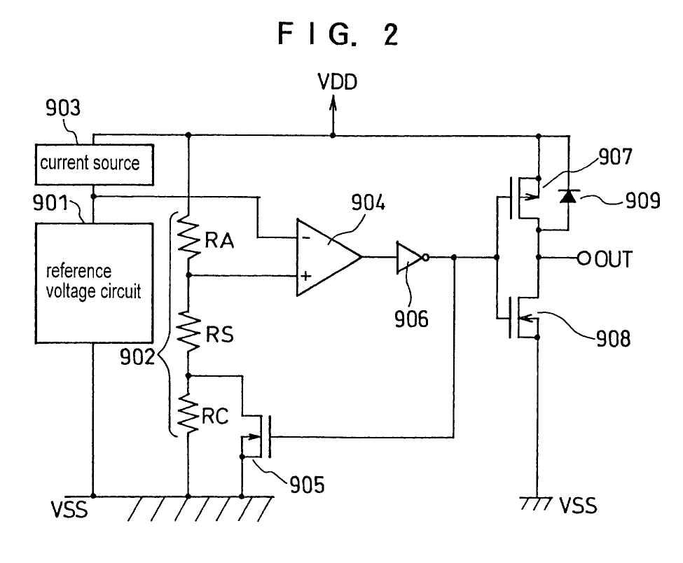

FIG. 2 is a circuit diagram, partly in block diagram, showing a configuration of one embodiment of a voltage detector to which the bleeder resistance circuit according to the present invention is applied.

While for the sake of simplicity, an example of a circuit is shown which is simple in configuration, the function(s), as may be necessary, may be added to the actual products.

The fundamental circuit elements of the voltage detector are a current source 903, a reference voltage circuit 901, a bleeder resistance circuit 902 and an error amplifier 904, and in addition thereto, an inverter 906, N-channel transistors 905 and 908, a P-channel transistor 907 and the like are provided therein. A part of the operation of the voltage detector will hereinafter be described simply.

When VDD is equal to or larger than a predetermined releasing voltage, the N-channel transistors 905 and 908 are both turned OFF, while the P-channel transistor 907 is turned ON so that VDD is outputted through an output terminal OUT.

The input voltage of the error amplifier 904 at this time becomes (RB+RC)/(RA+RB+RC)×VDD.

When VDD is decreased to become equal to or smaller than the detected voltage, VSS is outputted through the output terminal OUT. At this time, the N-channel transistor 905 is in the ON state, and the input voltage of the error amplifier 904 becomes RB/(RA+RB)×VDD.

In such a manner, the basic operation thereof is carried out by comparing the reference voltage which has been generated in the reference voltage circuit 901 and the voltage which has been obtained by the voltage division in the bleeder resistance circuit 902 with each other in the error amplifier 904. Therefore, the accuracy of the voltage which is obtained by the voltage division in the bleeder resistance circuit 902 becomes very important. Thus, if the accuracy of the voltage division in the bleeder resistance circuit 902 is poor, then the input voltage to the error amplifier 904 is deviated so that the predetermined releasing or detected voltage can not be obtained. By employing the bleeder resistance circuit according to the present invention, even after the IC is resin-packaged, the highly accurate voltage division becomes possible. Therefore, the product yield of the ICs is improved and also it becomes possible to manufacture the more accurate voltage detectors.

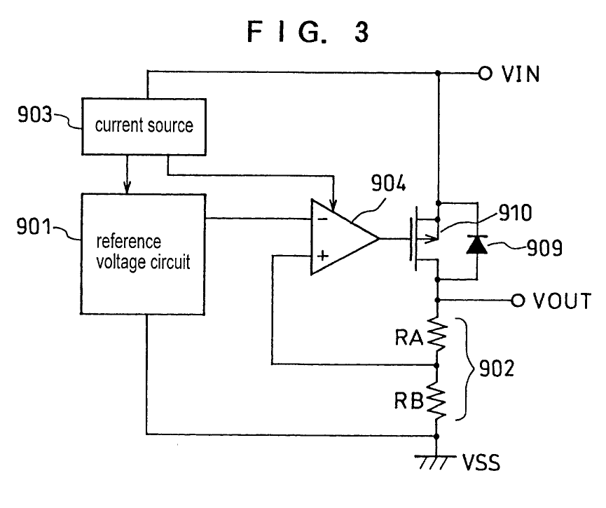

FIG. 3 is a circuit diagram, partly in block diagram, showing a configuration of a voltage regulator to which the bleeder resistance circuit according to the present invention is applied.

While for the sake of simplicity, an example of a circuit is shown which is simple in configuration, the function(s), as may be necessary, may be added to the actual products.

The fundamental circuit elements of the voltage regulator are a current source 903, a reference voltage circuit 901, a bleeder resistance circuit 902, an error amplifier 904, a P-channel transistor 901 acting as a current control transistor, and the like. A part of the operation of the voltage regulator will hereinbelow be described simply.

The error amplifier 904 compares the voltage which has been obtained by the voltage division in the bleeder resistance circuit 902 and the reference voltage which has been obtained in the reference voltage circuit 901 with each other to supply the P-channel transistor 910 with the gate voltage which is required to obtain a fixed output voltage VOUT which is free from the influence of the input voltage VIN and the temperature change at all. In the voltage regulator as well, similarly to the case of the voltage detector which was described with reference to FIG. 2, the basic operation thereof is carried out by comparing the reference voltage which has been generated in the reference voltage circuit 901 and the voltage which has been obtained by the voltage division in the bleeder resistance circuit 902 with each other in the error amplifier 904. Therefore, the accuracy of the voltage which is obtained by the voltage division in the bleeder resistance circuit 902 becomes very important. Thus, if the accuracy of the voltage division in the bleeder resistance circuit 902 is poor, then the input voltage to the error amplifier 904 is deviated so that the predetermined output voltage VOUT can not be obtained. By employing the bleeder resistance circuit according to the present invention, even after the IC is resin-packaged, the highly accurate voltage division becomes possible. Therefore, the product yield of the ICs is improved and also it becomes possible to manufacture the more accurate voltage regulators.

As set forth hereinabove, a thin film resistor of a semiconductor device which is obtained by a manufacturing method according to the present invention is constituted of a P-type thin film resistor which is formed of a P-type semiconductor thin film and an N-type thin film resistor which is formed of an N-type semiconductor thin film. Therefore, even when the stress is applied thereto due to the resin-packaging, the changes of the resistance values of the individual resistors can be cancelled each other to hold the integrated initial resistance value as it is. In addition, since in a bleeder resistance circuit, the resistance value as one unit is defined on the basis of the resistance value which is formed by combining the P-type thin film resistor and the N-type thin film resistor with each other, the accurate voltage dividing ratio can be held. By employing such a bleeder resistance circuit, there is offered the effect that the highly accurate semiconductor devices, e.g., the semiconductor devices such as a voltage detector and a voltage regulator can be obtained.

In addition, according to the method of manufacturing a semiconductor device of the present invention, in the process of forming the N-type source region 501 and the N-type drain region 502 of the NMOS transistor region 708, at the same time, the N-type resistance region 704 is formed in the N-type polycrystalline silicon resistor 706, while in the process of forming the P-type source region 503 and the P-type drain region 504 of the PMOS transistor region 709, at the same time, the P-type low resistance region 701 is formed in the P-type polycrystalline silicon resistor 703. Therefore, there is offered the effect that the manufacturing process can be simplified.

While the present invention has been particularly shown and described with reference to the preferred embodiments, it will be understood that the various changes and modification will occur to those skilled in the art without departing from the scope and spirit of the invention. The scope of the invention is therefore to be determined solely by the appended claims.

What is claimed is:

1. A method of manufacturing a semiconductor device in which an NMOS transistor and a PMOS transistor are both formed on a semiconductor substrate, and an N-type thin film resistor formed of an N-type semiconductor thin film on a field oxide film and a P-type thin film resistor formed of a P-type semiconductor thin film thereon are combined with each other to form a semiconductor thin film resistor, said method comprising: the process of forming simultaneously a source/drain region of said NMOS transistor and a low resistance region of said N-type thin film resistor; and the process of forming simultaneously a source/drain region of said PMOS transistor and a low resistance region of said P-type thin film resistor.

2. A method of manufacturing a semiconductor device according to claim 1, wherein said semiconductor thin film is a polycrystalline silicon film.

3. A method of manufacturing a semiconductor device according to claim 1, wherein said semiconductor thin film resistor is formed of the same film as that of each of a gate electrode of said NMOS transistor and a gate electrode of said PMOS transistor.
